(19) United States
(12) Patent Application Publication
(10) Pub. No.: US 2004/0026768 A1
(43) Pub. Date: Feb. 12, 2004

(54) Semiconductor dice with edge cavities

(76) Inventors: Reginald T. Taar, Quezon City (PH); Anthony H. Dajac, Cavite (PH); Carlo C. Tiongson, Cavite (PH)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/214,929

(22) Filed: Aug. 8, 2002

(51) Int. Cl. H01L 23/02

(52) U.S. Cl. 257/686

(57) ABSTRACT

A rounded wafer blade and stacked semiconductor package having a die with a cavity defined by a curved lower surface thereof. The curved lower surface and cavity allow for wire bonding directly therebelow at the top surface of another die of the semiconductor package. Additionally, wire bonding may proceed at a surface of the die opposite the curved lower surface without significant impact on a structural integrity of the die.

### BACKGROUND

Embodiments described relate to semiconductors. In particular, embodiments described relate to stacked dice semiconductor packages.

In the fabrication of integrated circuits, semiconductor wafers are processed and sliced into individual dice. The dice may then be used in a wide variety of devices. For example, a die may be used in an electronic device by being electronically coupled to a printed circuit board (PCB) of the device. However, prior to such an electronic coupling, packaging takes place. Packaging is the manner by which a semiconductor wafer is separated into individual dice which are then protected in various package forms. The protective packages prevent damage to the dice and provide an electrical path to the circuitry of the die.

The package includes a protective package substrate having a surface to which the die is secured and electronically coupled. In many cases, the die is a lower die having a top surface to which an upper die is secured. The resulting semiconductor package is often referred to as being of a “stacked” dice configuration. Stacked dice configurations may include more than two dice. The stacked dice may be secured to the package substrate by an adhesive or underfill.

Once a die is firmly in position, electrical coupling between the individual die and the package substrate is achieved by wire bonding. Wire bonding includes physically coupling wires between metal contacts located at the top surface of the die and bond pads located at the top surface of the package substrate. However, as noted above, an upper die may be placed on top of a lower die. Therefore measures may be taken to ensure that the metal contacts at the top surface of the lower die are exposed for wire bonding and coupling to the package substrate.

In order to provide access to the metal contacts at the top surface of the lower die, the lower die may be wider than the upper die. In this manner, the metal contacts may be positioned near a perimeter of the top surface of the lower die and remain uncovered by the upper die which is centrally located above the lower die. However, this requires that each die of a stacked package be smaller than the die below it. This leads to a stacked package with a pyramid configuration, with die size decreasing as the number of stacked dice increases. As a result, each die in the stack must have a different size, which increases manufacturing costs. Also, smaller dice cannot contain as much circuitry, hampering the circuit design.

Alternatively, each die may be of an elongated or rectangular shape with the upper die positioned perpendicular to, or otherwise offset from, the lower die when secured thereto. In this manner, a portion of the top surface of the lower die will remain uncovered by the upper die. The metal contacts for the lower die may be located at this portion of the top surface of the lower die and remain free for wire bonding. However, this approach leaves some areas of the periphery of the top of the lower die unavailable for electrical contacts because those areas are located below overlapping portions of the upper die.

In another alternative, the upper die may be secured indirectly to the lower die by the use of spacers therebetween. That is, the top surface of the lower die is only directly covered at locations where spacers are secured thereto. Spacers are generally silicon-based projections preventing the upper die from directly contacting the top surface of the lower die. The upper and lower dice are each secured to the spacers leaving the majority of the top surface of the lower die free to accommodate metal contacts accessible for wire bonding. However, due to the spacers, this configuration involves an increase in manufacturing costs and an increase in the vertical profile of the package.

### BRIEF DESCRIPTION OF THE DRAWINGS

FIG. 1 is a side view of an embodiment of a semiconductor package having an upper die with a cavity formed with a curved wafer blade tip.

FIG. 2A is side view of an embodiment of a curved wafer blade tip applied to a semiconductor wafer.

FIG. 2B is an enlarged side view of the curved wafer blade tip of FIG. 2A.

FIG. 2C is a side view of an embodiment of a separation blade applied to the semiconductor wafer of FIG. 2A.

FIGS. 3A, 3B are side views of an embodiment of a lower die secured to a package substrate.

FIGS. 4A, 4B are side views of an upper die secured to the lower die of FIG. 3B.

FIG. 5 is an enlarged view of an arm of the upper die of FIG. 4 subjected to wire bonding.

FIG. 6 is a flow chart of a method embodiment of forming a semiconductor package.

### DETAILED DESCRIPTION

In the following description, numerous specific details are set forth. However, it is understood that embodiments of the invention may be practiced without these specific details. In other instances, well-known circuits, structures and techniques have not been shown in detail in order not to obscure an understanding of this description.

References to “one embodiment”, “an embodiment”, “example embodiment”, “various embodiments”, etc., indicate that the embodiment(s) of the invention so described may include a particular feature, structure, or characteristic, but not every embodiment necessarily includes the particular feature, structure, or characteristic. Further, repeated use of the phrase “in one embodiment” does not necessarily refer to the same embodiment, although it may.

Various embodiments include a die with a recess, or cavity, disposed at a periphery of the die, a stack of dice including a die with such a cavity, a wafer blade with a curved blade tip for creating the cavity, and a method of using the blade to create the cavity. The cavity in an upper die may permit space for electrical connections to a lower die disposed beneath the upper die.

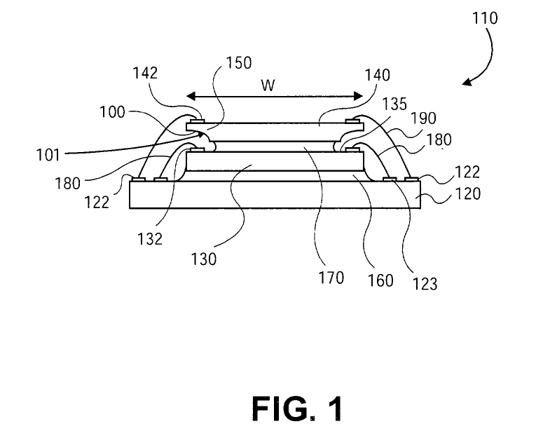

Referring now to FIG. 1, a semiconductor package 110 is shown. The semiconductor package 110 includes a package substrate 120 to which a lower die 130 is secured with a first adhesive 160. The first adhesive 160 may be any suitable adhesive, such as a polymer epoxy, dry film, or other adhesive material. An upper die 140 is similarly secured to the lower die 130 with a second adhesive 170, thus providing a stacked configuration to the semiconductor package 110. The second adhesive 170 may or may not be the same material as that of the first adhesive 160. In some embodiments, no spacers are used between the lower die 130 and the upper die 140, and only the thickness of the second adhesive 170 separates the lower and upper dice.

The upper die 140 and the lower die 130 may include various types of integrated circuit devices (for example, flash memory devices) electrically coupled to the package substrate 120. This electrical coupling may be achieved with wires 190 extending from electrical contacts 142 on upper die 140 to electrical contacts 122 on package substrate 120, and with wires 180 extending from electrical contacts 132 on lower die 130 to electrical contacts 123 on package substrate 120. The wires 180, 190 may be of gold, aluminum, or other electrically conductive material. Referring specifically to the upper die 140, an outer wire 190 is coupled at one end to an upper contact 142 of the upper die 140 and at the other end to an outer bond pad 122 of the package substrate 120. In this manner, the internal circuitry of the upper die 140 is electrically connectable to the package substrate 120. The internal circuitry of the lower die 130 is also electrically connectable to the package substrate 120 as described below.

The circuitry of the lower die 130 is accessible in a manner that allows the upper die 140 to be secured directly to, and positioned in direct alignment with, the lower die 130. This is done in a way that also allows the dice 130, 140 to be substantially the same size. That is, the dice 130, 140 may be of about the same width and length. Additionally, the profile of the semiconductor package 110 need not be increased in order to allow for electrical coupling between the lower die 130 and the package substrate 120.

Continuing with reference to FIG. 1, the upper die 140 includes an arm portion 150 near sides of the upper die 140. In the embodiment shown, the upper contact 142, as noted above, is located at the arm portion 150 at the top surface of the upper die 140. The arm portion 150 includes a curved lower surface 100 which maybe located on the opposite side of the arm portion 150 from the upper contact 142. A cavity 101 is defined by the shape of the curved lower surface 100, allowing for access to contacts 132 on the lower die 130.

The cavity 101 allows space for the lower contact 132 at the top surface 135 of the lower die 130 and for the attached wire 180. This is the case even though the upper die 140 is secured to the same top surface 135, and extends as far out as lower die 130. As described further herein, the curved lower surface 100, and therefore, the cavity 101, may be formed by a wafer blade having a curved tip portion.

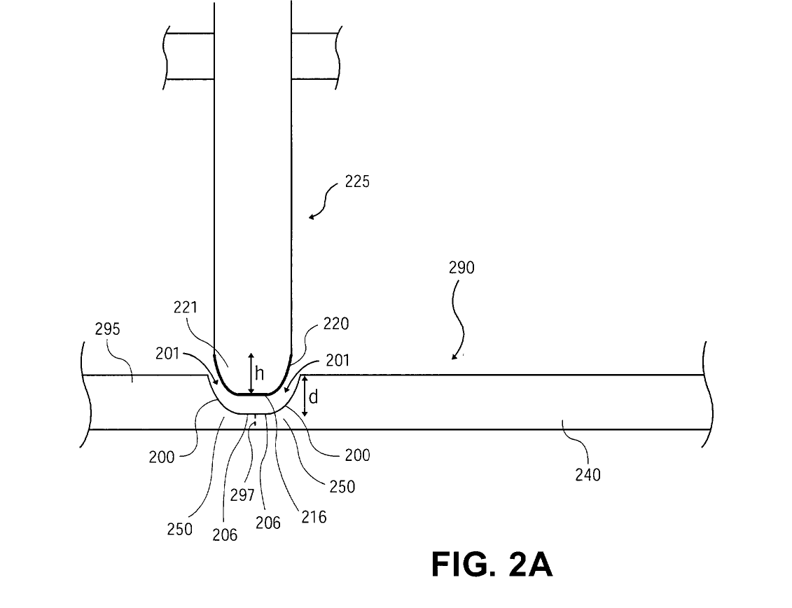

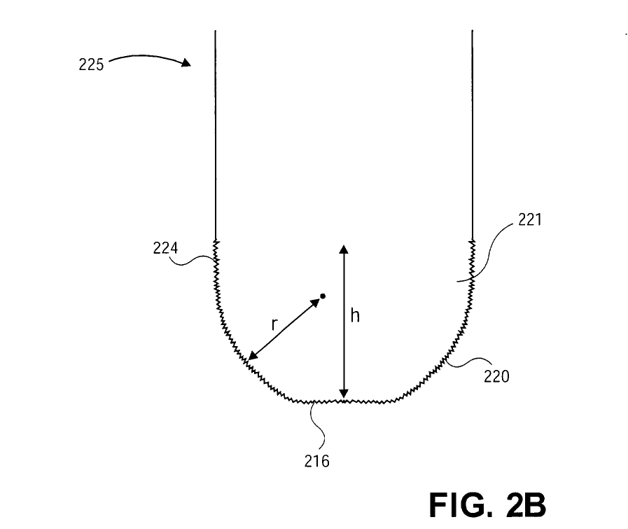

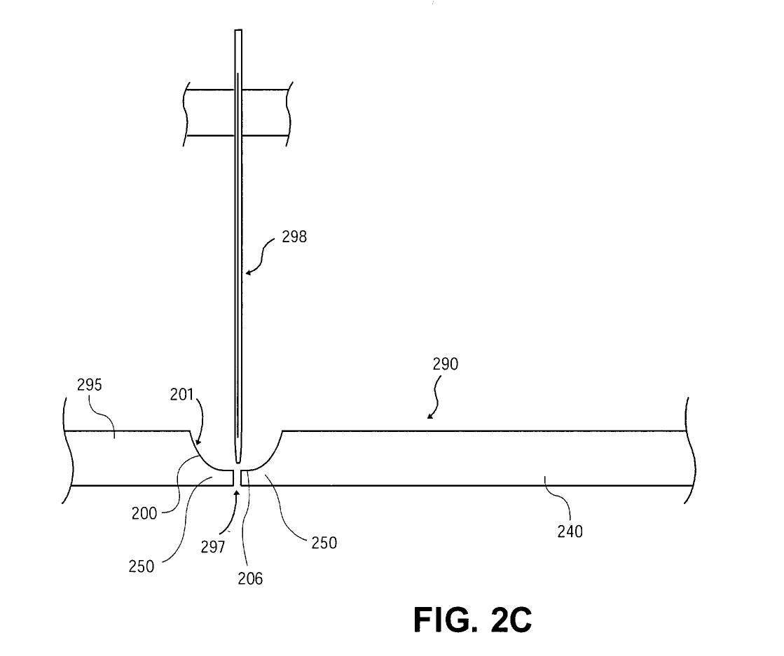

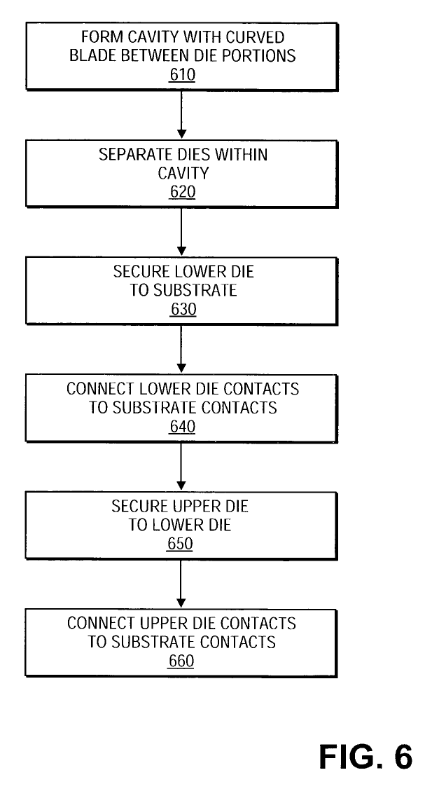

FIGS. 2A-2C show the formation of cavities along the edges of dice, according to one embodiment of the invention. The first two blocks of FIG. 6 show a flow chart of a method to form the cavities, according to one embodiment of the invention. It is understood that the embodiment of FIG. 6 and the embodiment of FIGS. 2A-2C may be implemented independently of each other, or may be implemented together.

Referring to FIG. 6, a cavity is formed between dice on a wafer, using a curved blade. Referring to FIGS. 2A and 2B, the wafer blade 225 and the resulting cavity 201 formed in the wafer 290 by the wafer blade 225 are shown. A portion of the wafer blade 225 is shown in edge view. The wafer blade 225 may be referred to as a ‘curved blade’ and/or a ‘crescent blade’, due to the curved configuration of the cutting surface of the wafer blade 225. In one embodiment, wafer blade 225 has an overall disk shape and is rotated about its central axis, with the cutting surface located along the outer portion, or tip 221, of the peripheral region of the disk. In one embodiment, the cutting portions of tip 221 may include portions which are not actually curved, such as the flat portion 216 of the tip 221. Additionally, embodiments of the curved portions 220 may or may not actually be a true curve.

Referring to FIG. 2A in particular, the wafer blade 225 is shown applied to a wafer 290 between dice 240, 295 of the wafer 290, to form a cavity 201. Die 240 and die 295 represent the portions of wafer 290 that are to be separated into individual dice. In one embodiment, the tip 221 of the wafer blade 225 has a height (h) that is at least as large as the depth (d) of a cavity 201 to be formed, so that the wafer 290 will only come in contact with the cutting surfaces of wafer blade 225. As shown in FIG. 2C, the individual dice 240, 295 are to be separated at the demarcation 297 in a subsequent operation. Therefore, the cavities 201, and the associated arm portions 250 of the adjacent dice 240, 295 may be simultaneously formed for both dice 240, 295 by a single application of the wafer blade 225.

In one embodiment, the wafer blade 225 may have a diameter of between about 2 inches and about 4 inches, but other embodiments may use other sizes. In some embodiments, the wafer blade 225 and tip 221 have a thickness between about 350 microns and about 900 microns. In a particular embodiment, the wafer blade 225 is about 500 microns thick for an industry standard size wafer 290 of 6.5 mils in wafer thickness.

Depending on factors such as wafer materials and the thickness of the wafer 290, the wafer blade 225 may be rotated at a particular angular rate, while the wafer 290 may be advanced linearly at a particular rate. In this manner, the cavities 201 may be formed between adjacent dice. In a particular embodiment in which a rectangular matrix of dice is laid out on a wafer, a first set of multiple parallel cavities may be formed on the wafer 290 by making multiple passes with the wafer blade 225 between rows of dice, and a second set of multiple parallel cavities may be formed on the wafer 290 by making multiple passes between columns of dice. The two operations may ultimately result in cavities for every die on the wafer that is to have a cavity.

Referring to FIG. 6, at block 620 adjacent dice are separated from one another within the cavity between the adjacent dice. Referring to FIG. 2C, after a particular cavity is formed, in one embodiment a thinner blade 298 may be used to separate the individual dice by cutting through the wafer 290 within cavity 201. While in one embodiment all cavities 201 on the wafer 290 are formed before any dice are separated with blade 298, in another embodiment the operations to create cavities and perform separation are both performed on some areas of wafer 290 before either operation is performed on other areas of wafer 290. An enhanced camera may be employed to precisely position the wafer blade 225 and the secondary blade 298 before their respective applications. While in one embodiment a cavity is formed along each edge of every die in the manner described, other embodiments may employ a subset of this technique. For example, 1) cavities may be formed along at least one edge of every die on the wafer, 2) cavities may be formed along all edges of only some dice on the wafer, 3) cavities may be formed for only some edges of only some dice of the wafer, and 4) any combination of these.

In one embodiment the material of the wafer 290 may be based on silicon, silicon dioxide, or other hard material. The cutting surface 224 of the tip 221 of the wafer blade 225 may include a diamond grid. This is denoted in FIG. 2B by the jagged appearance of the surface 224. The diamond grid surface allows for smooth sawing by the tip 221 through the material of the wafer 290. In this manner the cavities 201 and the curved lower surfaces 200 may be formed without cracking or misshaping the arm portions 250 or other portions of the dice 240, 295. In an alternate embodiment, the roughened surface 224 may be provided by nickel plating. Other techniques may also be used.

Continuing with reference to FIG. 2A, the wafer 290 may be of various thicknesses, such as a thickness of between about 5 mils and about 10 mils, including industry standard sizes of about 6.5 mils and about 8 mils. In one embodiment, where the wafer 290 is an industry standard size of about 6.5 mils, the depth (d) of the cavity 201 may be between about 4 mils and about 6 mils, for example about 5.5 mils, leaving the thinnest part of the arm portion 250 at about 1.0 mils. The tapering shape provided by the wafer blade 225 allows the arm portions 250 to withstand stress forces that may be encountered during assembly, due to the increasing thickness of the arm with distance from the edge of the die. Similarly, in another embodiment of the invention where the wafer 290 is an industry standard size of about 8 mils., the depth (d) of the cavities 201 may be between about 4 mils and about 6.5 mils, preferably about 5 mils to result in a minimum thickness of about 3 mils.

Referring to FIG. 2B in particular, an enlarged view of the wafer blade 225 is shown. The tip 221 is shown and distinguished by its roughened surface 224 as noted above. Additionally, the tip 221 extends to a height (h) that is at least about the depth (d) of the cavities 201 (as shown in FIG. 2A). This ensures that no other portion of the wafer blade 225 encounters or unintentionally damages the wafer 290 during formation of the cavities 201 as noted above.

In the embodiment shown, curved portions 220 include true curves having a radius (r). However, as described further below, true curves are not required. In one embodiment, the radius (r) is between about 10 microns and about 40 microns, such as about 25 microns. However, other radius sizing may be employed, depending upon factors such as the size of the dice 240, 295, cavities 201, or curved surfaces 200 to be used.

In the embodiment shown in FIGS. 2A and 2B, the curved portions 220 and curved lower surfaces 200 appear to be true curves, i.e., without straight portions or angular transitions. However, the curved portions 220 may actually have shapes other than, or in addition to, a true curve. For example, in an alternate embodiment, the curved lower surfaces 200, formed by the similarly shaped curved portions 220, may include two or more straight portions.

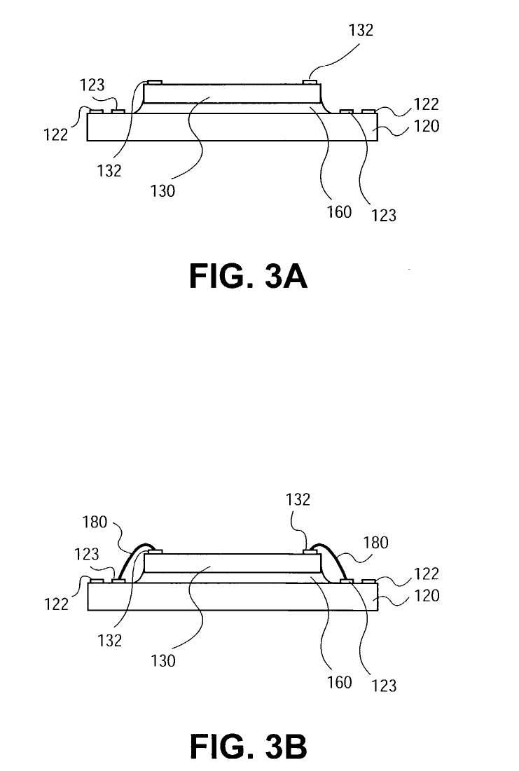

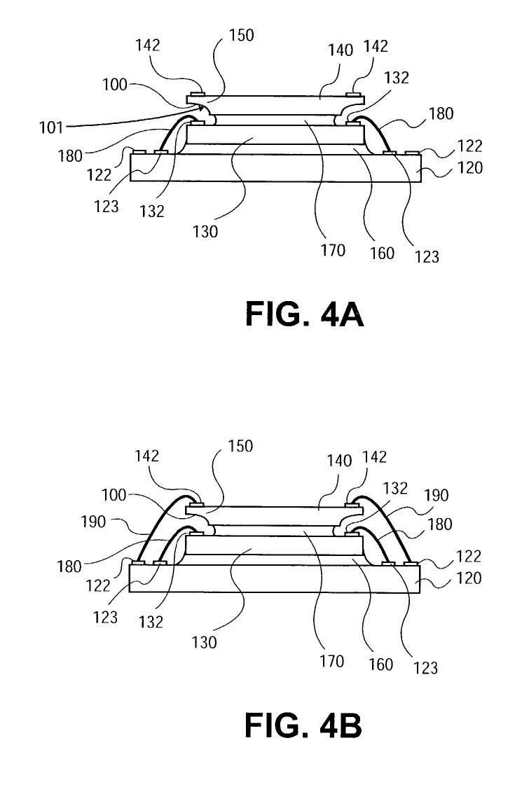

FIGS. 3A, 3B, 4A and 4B show various stages in the assembly of a semiconductor package, according to one embodiment of the invention. Blocks 630-660 of FIG. 6 show a flow chart of a method of assembling a semiconductor package, according to one embodiment of the invention. Although the text may sometimes refer to both FIG. 6 and to FIGS. 3A-4B, it is understood that the method of FIG. 6 and the package of FIGS. 3A-4B may be implemented independently of each other. For ease in identification, FIGS. 3A-4B use the same identifiers as FIG. 1 to indicate the various parts of the assembly.

Referring to FIG. 6, at block 630 it is assumed that the dice to be used in the assembly operation have already been separated as described in blocks 610-620. The lower and upper dice described in blocks 630-660 may be identical or may be different, and may be from the same wafer or from different wafers.

At block 630 the lower die is secured to a substrate. With reference to FIG. 3A, lower die 130 is secured to package substrate 120 using adhesive 160. While in one embodiment placement of lower die 130 is performed by a conventional pick and place device, other embodiments may use other known or yet-to-be developed techniques for placement.

Referring again to FIG. 6, at block 640 the electrical contacts on the lower die are connected to the electrical contacts on the substrate. With reference to FIG. 3B, the connections may be made with wires 180 extending from electrical contacts 132 on lower die 130 to electrical contacts 123 on substrate 120. In one embodiment wire bonding is used to make the connections, but other techniques may also be used. While in one embodiment all electrical contacts 132 on lower die 130 are connected to substrate 120, in other embodiments only some of the electrical contacts 132 on lower die 130 are so connected.

Referring again to FIG. 6, at block 650 an upper die is secured to the lower die. With reference to FIG. 4A, upper die 140 is secured to lower die 130 using adhesive 170. Adhesive 170 may be the same type or a different type than adhesive 160 While in one embodiment placement of upper die 140 is performed by a conventional pick and place device, other embodiments may use other known or yet-to-be developed techniques for placement.

Referring again to FIG. 6, at block 660 the electrical contacts on the upper die are connected to the electrical contacts on the substrate. With reference to FIG. 4B, the connections may be made with wires 190 extending from electrical contacts 142 on upper die 140 to electrical contacts 122 on substrate 120. In one embodiment wire bonding is used to make the connections, but other techniques may also be used. While in one embodiment all electrical contacts 142 on upper die 140 are connected to substrate 120, in other embodiments only some of the electrical contacts 142 on upper die 140 are so connected. Wires 190 may be the same type or a different type than wires 180.

As can be seen from FIG. 4B, the cavity formed by curved surface 100 on upper die 140 permits space for contact 132 and the attached wire 180, even though the arm portion 150 of upper die 140 may extend out over contact 132.

One or both of adhesives 160, 170 may require curing. In one embodiment, curing may be achieved by placing the substrate-dice assembly into a semiconductor bake oven for a sufficient time to cure the adhesive. A particular embodiment may require baking at more than 100° C. for a time between about 15 minutes and about 3 hours.

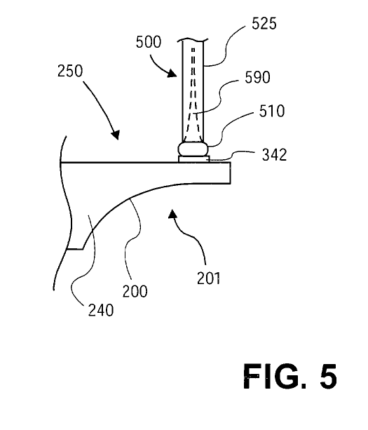

The wires may be attached to the associated electrical contacts through various means. FIG. 5 shows a wire bonding technique, according to one embodiment of the invention. In the illustrated embodiment, an electrical contact 342 is located at an arm portion 250 of a die 240. The lead 500 may include a housing 525 for a wire 590. The wire 590 may include conventional electrically conductive wire bonding material such as gold or aluminum, or may include other materials. Additionally, the wire 590 may terminate at a wire ball 510 shaped to maximize the interface between the wire 590 and the electrical contact 342. The wire ball 510 may be placed in contact with the electrical contact 342 and ultrasonic energy applied for between about 10 milliseconds (msec) and about 20 msec through the lead for bonding to the electrical contact 342. Other means of attaching wires to electrical contacts may also be used.

The application of ultrasonic energy through the lead 500 may impart a force on die 240 perpendicular to the surface of die 240, which in turn may impart a shear force on arm portion 250 that increases with distance from electrical contact 342 due to torque. However, the tapering curved shape of arm portion 250 provides increasing thickness, and therefore increasing resistance to shear forces, with increasing distance from electrical contact 342. This permits the use of a thin outer area of arm portion 250 without subjecting the entire arm portion 250 to cracking that might occur if the entire arm portion 250 were uniformly thin.

Embodiments described above include a wafer blade, a method of using the wafer blade, and a stacked dice configuration that allow an upper die to be secured to a similarly sized lower die in a manner that does not increase the profile of the configuration. Additionally, space within the subsequently formed package is efficiently used. Furthermore, reliability and structural integrity of the upper die is not sacrificed in order to provide electrical access to the lower die.

Although exemplary embodiments describe particular wafer blades, dice, and stacked dice configurations, additional embodiments are possible. Additionally, many changes, modifications, and substitutions may be made without departing from the spirit and scope of these embodiments.

We claim:

1. A wafer blade comprising a blade tip having a curved portion to cut into a surface of a wafer to form a curved surface at a periphery of a die.

2. The wafer blade of claim 1 wherein the curved surface defines a cavity, said blade tip having a height at least about a depth of the cavity.

3. The wafer blade of claim 1 wherein said blade tip is of a thickness between about 350 microns and about 900 microns.

4. The wafer blade of claim 1 wherein the curved portion includes a straight portion.

5. The wafer blade of claim 1 wherein the curved portion includes a true curve.

6. The wafer blade of claim 5 wherein the true curve includes a radius of between about 10 microns and about 40 microns.

7. The wafer blade of claim 1 wherein said blade tip includes a roughened surface.

8. The wafer blade of claim 7 wherein the roughened surface includes at least one of a diamond grid and nickel plating.

9. A die comprising a curved first surface portion to define a cavity, the cavity to allow access to a portion of a second surface of a device when said die is secured to the second surface.

10. The die of claim 9 wherein the die is an upper die, the device is a lower die, and the second surface includes a contact for wire bonding, the cavity to allow space for access to the contact.

11. The die of claim 9 comprising a thickness of between about 5 mils and about 10 mils.

12. The die of claim 9 wherein the curved first surface portion is a true curve.

13. The die of claim 9 wherein the curved first surface portion includes a straight portion.

14. The die of claim 9 wherein the curved first surface portion is located at an arm portion of the die, the arm portion having a top surface opposite the curved first surface portion, the top surface to accommodate an electrical contact.

15. The die of claim 14 wherein the curved first surface portion includes a transition from a main body of the die to a thinnest portion of the die at an edge of the die.

16. A semiconductor package comprising:
a lower die; and
an upper die secured to the lower die and in substantially direct alignment with the lower die, the upper and lower dice of substantially equal dimensions, the upper die including an arm portion with a top surface having a first electrical contact secured thereto, the arm portion to provide clearance for an electrical connection to a second electrical contact on the lower die.

17. The semiconductor package of claim 16, further comprising a wire electrically connected to the second electrical contact.

18. The semiconductor package of claim 17, wherein the wire includes at least one of gold and aluminum.

19. The semiconductor package of claim 16 wherein the arm portion includes a curved lower surface opposite the top surface.

20. The semiconductor package of claim 19 further comprising:
a package substrate;
a first wire electrically connected from the package substrate to the first electrical contact; and
a second wire electrically connected from the package substrate to the second electrical contact.

21. A system comprising:
a printed circuit board; and
a semiconductor package secured to the printed circuit board, the semiconductor package having a spacer-less stacked dice configuration with an upper die having a curved portion of a lower surface at a periphery of the upper die, the upper die secured in direct alignment with a lower die, the upper and lower dice of substantially the same dimensions.

22. The system of claim 21 wherein the spacer-less stacked dice configuration further includes an additional die secured to the upper die.

23. The system of claim 21, further comprising an electrical connection between the printed circuit board and an electrical contact coupled to the lower die, the electrical contact disposed within a space defined by the curved portion.

24. A method comprising forming a cavity in a wafer surface with a first wafer blade having a blade tip with a curved portion.

25. The method of claim 24 further comprising applying a second wafer blade to the wafer within the cavity to separate a die having a curved surface from the wafer.

26. The method of claim 24 wherein the curved portion includes at least one of a true curve and a straight portion.

27. A method comprising securing an upper die to a lower die to form a stacked dice configuration, the upper die having an arm portion with a curved lower surface defining a cavity to allow access to a portion of a top surface of the lower die.

28. The method of claim 27 further comprising securing the stacked dice configuration to a package substrate to form a semiconductor package.

29. The method of claim 28 wherein said securing of the upper die to the lower die and said securing of the stacked dice configuration to the package substrate are accomplished with underfill material adhesive.

30. The method of claim 28 further comprising:
wire bonding the package substrate to the lower die; and
wire bonding the package substrate to the upper die at the arm portion.
